(19) United States
(12) Patent Application Publication
(10) Pub. No.: US 2008/0157384 A1
(43) Pub. Date: Jul. 3, 2008

(54) Alignment Key of Semiconductor Device and Method of Manufacturing the Same

(76) Inventor: Haeng Leem Jeon, Anyang-si (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/854,739

(22) Filed: Sep. 13, 2007

(30) Foreign Application Priority Data
Dec. 27, 2006 (KR) 10-2006-0134852

(51) Int. Cl. H01L 23/48; H01L 21/441

(52) U.S. Cl. 257/770; 438/685; 257/E23.179; 257/E21.477

(57) ABSTRACT

Disclosed is a method of manufacturing an alignment key of a semiconductor device. According to an embodiment, the method includes forming an insulating layer on a semiconductor substrate on which a cell region and a scribe line are defined, forming a photoresist pattern on the insulating layer and etching the insulating layer using the photoresist pattern as an etch mask so as to form a contact hole on the cell region and a mark hole on the scribe line, depositing a metal layer in the contact hole and the mark hole, and planarizing the metal layer so as to form a contact and an alignment mark. The mark hole can be the same size as the contact hole. In addition, the mark hole can be formed in plurality on the scribe line.

### CROSS-REFERENCE TO RELATED APPLICATION

The present application claims the benefit under 35 U.S.C. §119 of Korean Patent Application No. 10-2006-0134852, filed Dec. 27, 2006, which is hereby incorporated by reference in its entirety.

### BACKGROUND

When a semiconductor device is manufactured, a predetermined thin film is formed on a wafer and a lithography process is performed so as to form a desired circuit pattern, so that various conductive patterns including a contact hole can be formed on the wafer.

The lithography process includes processes of coating an etching layer with a photoresist layer, exposing the photoresist layer by using a photo mask, and developing the exposed photoresist layer. The etching layer is etched using the photoresist pattern described above, so that various conductive patterns including a contact hole can be formed.

In order to perform the exposure process, the wafer must be precisely aligned relative to the photo mask. This is because overlay accuracy between upper and lower layers is very important in the process of manufacturing the semiconductor device having a multi-layer structure.

A stepper used in the exposure process repeatedly aligns the wafer relative to a reticle and transfers the circuit pattern of the reticle onto the wafer. The alignment process between the wafer and the reticle includes two steps: search alignment and enhanced global alignment (EGA).

The search alignment is a process of checking an alignment state of the wafer by roughly detecting the position of an alignment key formed on the wafer. The EGA refers to a process of precisely aligning the alignment key in the wafer after the search alignment.

The search alignment is performed by means of a Laser Scanning Alignment (LSA) sensor or a Filed Image Alignment (FIA) sensor according to manufacturing steps of the semiconductor device.

In general, in the manufacturing process of the semiconductor device, the position of the alignment key is detected by using the LSA sensor before a metal interconnection is formed, and the position of the alignment key is detected by using the FIA sensor after the metal interconnection has been formed.

Hereinafter, a method of forming the alignment key according to the related art will be described with reference to FIGS. 1 and 2.

After a transistor is formed on a semiconductor substrate 1, a Pre Metal dielectric (PMD) layer or an Inter Metal Dielectric (IMD) layer is deposited on the semiconductor substrate 1 so as to form an interlayer dielectric 2. Then the interlayer dielectric 2 is patterned through the lithography process to form a contact hole 3. Next, tungsten may be deposited in the contact hole 3, and a Chemical Mechanical Polishing (CMP) process is performed to form a contact 4, which is prepared to serve as a connection with respect to a metal interconnection that will be formed later. At this time, in order to perform the lithography process relative to the metal interconnection, the alignment key is patterned on a scribe line (B).

However, different from the fine sized contact holes 3, the related art alignment key is prepared in a chip in the form of a mark hole 5 having a size of few micrometers (μm). Accordingly, when the CMP process is performed after depositing tungsten in the contact hole 3 and the mark hole 5, a metal layer 4 deposited in the mark hole 5 has a relatively thin thickness, so erosion or a dishing phenomenon may occur in the edge part of the mark hole 5.

Accordingly, in the subsequent lithography process, the alignment key may not be detected by a search alignment sensor, causing the process fault.

### BRIEF SUMMARY

Embodiments of the present invention provide a method of manufacturing an alignment key of a semiconductor device, capable of improving alignment recognition by forming the alignment key to have a mark hole with a size identical to that of a contact hole when a planarization process is performed after a metal layer has been deposited.

A method of manufacturing an alignment key of a semiconductor device according to an embodiment includes forming an insulating layer on a semiconductor substrate on which a cell region and a scribe line are defined, forming a photoresist pattern on the insulating layer so as to form a contact hole on the cell region and a mark hole on the scribe line, depositing a metal layer in the contact hole and the mark hole, and planarizing the metal layer so as to form a contact and an alignment mark.

In addition, an alignment key of a semiconductor device according to an embodiment includes an insulating layer formed on a semiconductor substrate having a cell region and a scribe line, a contact hole formed in the cell region, a mark hole of contact hole size formed in the scribe line, and a contact and an alignment mark formed by depositing a metal layer in the contact hole and the mark hole, respectively.

### BRIEF DESCRIPTION OF THE DRAWINGS

FIGS. 1 and 2 are cross-sectional views representing a method of manufacturing an alignment key of a semiconductor device according to the related art;

FIGS. 3 to 6 are cross-sectional views representing a method of manufacturing an alignment key of a semiconductor device according to an embodiment of the present invention; and

FIG. 7 is a plan view schematically representing an alignment key of a semiconductor device according to an embodiment.

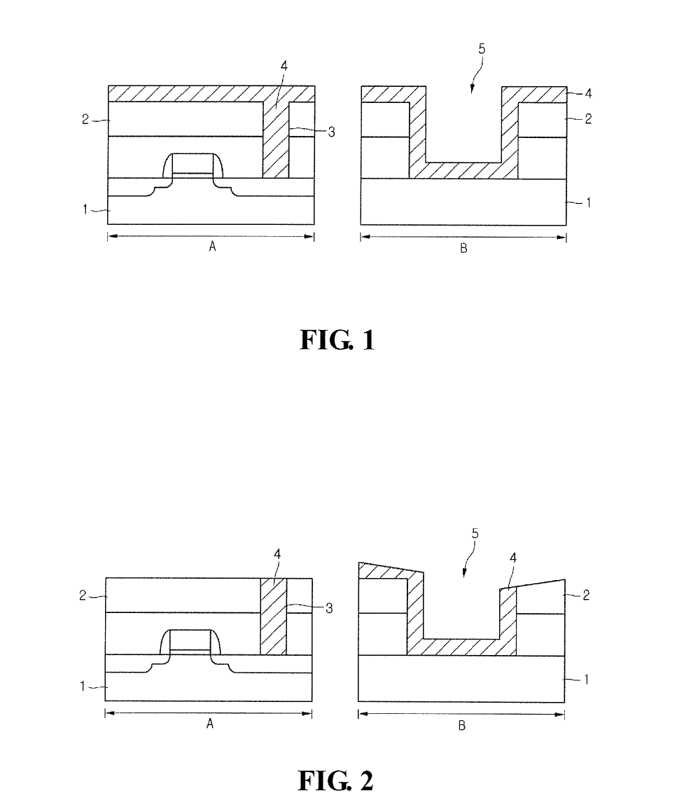

### DETAILED DESCRIPTION

Hereinafter, an alignment key of a semiconductor device and a method of manufacturing the same according to embodiments of the present invention will be explained with reference to the accompanying drawings.

FIG. 6 is a cross-sectional view representing the alignment key of a semiconductor device according to an embodiment.

Referring to FIG. 6, an embodiment of an alignment key includes an insulating layer 50 formed on a semiconductor substrate 10 that includes a cell region (A) and a scribe line (B), a contact hole 60 formed in the cell region (A), a mark hole 70 formed in the scribe line (B) and a contact 81 and an alignment mark 82 that are formed in the contact hole 60 and the mark hole 70, respectively.

The contact hole 60 has a size identical to that of the mark hole 70. For example, the contact hole 60 and the mark hole 70 can have a width of about 0.13 μm to 0.20 μm.

In an embodiment, a metal layer 80 deposited in the contact hole 60 and the mark hole 70 to form the contact 81 and the alignment mark 82 includes tungsten.

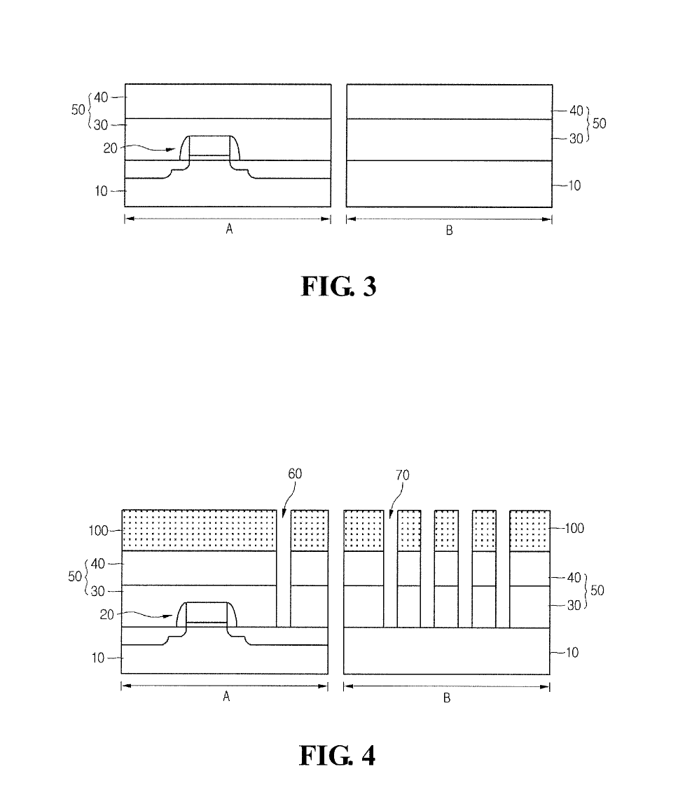

FIGS. 3 to 6 are cross-sectional views representing a method of manufacturing an alignment key of the semiconductor device according to an embodiment.

Referring to FIG. 3, an interlayer dielectric 50 can be formed on a semiconductor substrate 10 on which a cell region (A) and a scribe line (B) are defined.

A transistor structure 20 or a lower interconnection (not shown) can be provided on the semiconductor substrate 10 before forming the interlayer dielectric 50.

In one embodiment the cell region (A) of the semiconductor substrate 10 includes an active region and a transistor structure 20 formed on the cell region (A).

The interlayer dielectric 50 for forming a metal interconnection is formed on the cell region (A). At the same time, the interlayer dielectric 50 is formed on the scribe line (B). For example, the interlayer dielectric 50 can be formed by depositing a Pre-Metal Dielectric (PMD) 30 and Tetraethoxy silane (TEOS) 40.

Referring to FIG. 4, a photoresist layer can be coated on the semiconductor substrate 10 so as to form a photoresist pattern 100 that defines an area on which a contact hole 60 of the cell region (A) is formed and an area on which a mark hole 70 of the scribe line (B) is formed.

The interlayer dielectric 50 can be etched using the photoresist pattern 100 as an etching mask so as to form a contact hole 60 in the cell region (A) and form a mark hole 70 in the scribe line (B).

The contact hole 60 has a size identical to that of the mark hole 70, so that the contact hole 60 and the mark hole 70 represent the same state when they are planarized through a following Chemical Mechanical Polishing (CMP).

That is, the mark hole 70 has a width identical to that of the contact hole 60. For example, the mark hole 70 and the contact hole 60 can have a width of about 0.13 μm to 0.20 μm.

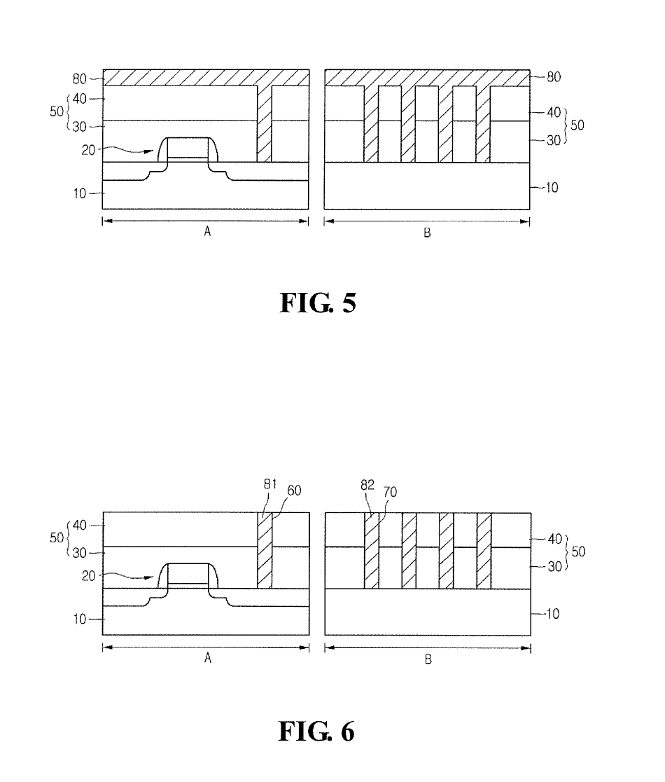

Referring to FIG. 5, after removing the photoresist pattern 100, a metal layer 80 can be formed by depositing metallic material, such as tungsten (W), on the interlayer dielectric 50 to form the contact serving as a metal interconnection of, for example, the transistor structure 20. As a result, tungsten is filled in the contact hole 60 and the mark hole 70.

Referring to FIG. 6, a CMP process is performed to planarize the metal layer 80, so that the contact 81 is formed in the cell region (A), and the alignment mark 82 is formed on the scribe line (B).

Since the contact hole 60 has a size identical to that of the mark hole 70, the contact hole 60 and the mark hole 70 can be planarized with the same condition during the CMP process, so a step difference may not occur therebetween. In embodiments, a plurality of mark holes 70 can be formed.

Accordingly, the erosion phenomenon or dishing effect does not occur in specific regions, such as at an edge region of the mark hole 70, so that a shape of the alignment key including a plurality of mark holes 70 is maintained as it is, thereby improving the alignment key recognition in the following lithography process.

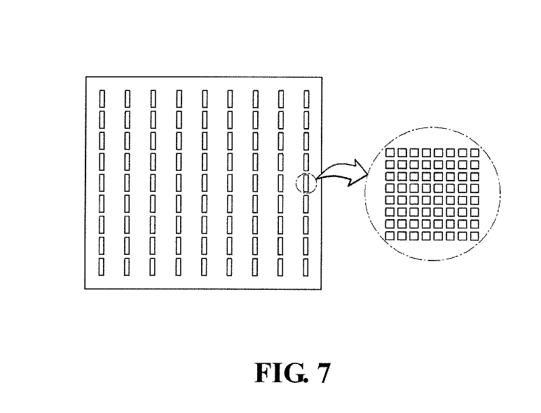

FIG. 7 is a plan view illustrating an alignment key of the semiconductor device according to an embodiment.

The alignment key may have a small size that may deviate from resolution of the search alignment sensor, for example, the Filed Image Alignment (FIA) sensor. Accordingly, embodiments of the present invention can provide a mark hole pattern including an array of mark holes as illustrated in FIG. 7.

That is, when the mask for forming the contact hole is manufactured, a pattern for the mark hole, which can be prepared in the form of a fine hole having, for example, the size of about 0.16 μm identical to the size of a contact hole, is formed on the mask, so that the alignment accuracy by exposure equipment can be improved even if the shape of the alignment key is maintained as it is.

In the method of manufacturing the alignment key of the semiconductor device according to the embodiment, the alignment key is formed in a shape identical to that of the contact hole in the cell region, thereby preventing the step difference that occurs when the gap-fill process is performed using tungsten.

In addition, the erosion phenomenon or the dishing phenomenon occurring during the planarization process is inhibited, so that the characteristic of the alignment key is improved in a following lithography process and the alignment accuracy is improved, thereby increasing the yield rate of the semiconductor device.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method of manufacturing an alignment key of a semiconductor device, the method comprising:
forming an insulating layer on a semiconductor substrate having a cell region and a scribe line;
forming a photoresist pattern on the insulating layer so as to form a contact hole on the cell region and a mark hole on the scribe line;
depositing a metal layer in the contact hole and the mark hole; and
planarizing the metal layer to form a contact in the contact hole and an alignment mark in the mark hole.

2. The method according to claim 1, wherein the contact hole is formed simultaneously with the mark hole.

3. The method according to claim 1, wherein the mark hole has a size identical to a size of the contact hole.

4. The method according to claim 1, wherein the contact hole and the mark hole have a width of about 0.13 μm to 0.20 μm.

5. The method according to claim 1, wherein the metal layer comprises tungsten.

6. The method according to claim 1, wherein planarizing the metal layer comprises performing a Chemical Mechanical Polishing (CMP) process.

7. An alignment key of a semiconductor device, comprising:
an insulating layer formed on a semiconductor substrate having a cell region and a scribe line;
a contact hole formed in the insulating layer on the cell region;
a mark hole formed in the insulating layer on the scribe line; and
a contact and an alignment mark that are formed by depositing a metal layer in the contact hole and the mark hole, respectively.

8. The alignment key according to claim 7, wherein the mark hole has a size identical to a size of the contact hole.

9. The alignment key according to claim 7, wherein the contact hole and the mark hole have a width of about 0.13 μm to 0.20 μm.

10. The alignment key according to claim 7, wherein the metal layer comprises tungsten.
